(19) United States
(12) Patent Application Publication
(10) Pub. No.: US 2019/0158038 A1
(43) Pub. Date: May 23, 2019

(54) CURRENT SOURCE CIRCUIT AND AMPLIFIER DEVICE

(71) Applicant: Murata Manufacturing Co., Ltd., Kyoto (JP)

(72) Inventor: Nobuyasu BEPPU, Kyoto (JP)

(21) Appl. No.: 16/190,552

(22) Filed: Nov. 14, 2018

(30) Foreign Application Priority Data
Nov. 17, 2017 (JP) 2017-222061

(51) Int. Cl. H03F 1/30; H03F 3/193; G05F 3/26; H03F 1/02

(52) U.S. Cl. CPC H03F 1/301; H03F 3/193; H03F 2200/447; H03F 1/0211; H03F 2200/451; G05F 3/262

(57) ABSTRACT

A current source circuit includes p-type transistors 21p and 22p, n-type transistors 11n and 12n, an output n-type transistor, and a resistance element connected in series between the n-type transistor 12n and a ground. A gate terminal G2 is connected to a gate terminal G1 and a drain terminal D2, a gate terminal G3 is connected to a gate terminal G4 and a drain terminal D3, and a gate terminal G4 is connected to a gate terminal G5. A current I₁ flows in sequence of the power supply terminal, the p-type transistor 21p, the n-type transistor 11n, and the ground, and a current I₂ flows in sequence of the power supply terminal, the p-type transistor 22p, the n-type transistor 12n, and the ground. The resistance element has a positive temperature coefficient causing a resistance value to increase with a temperature rise.

This application claims priority from Japanese Patent Application No. 2017-222061 filed on Nov. 17, 2017. The content of this application is incorporated herein by reference in its entirety.

### BACKGROUND OF THE DISCLOSURE

### 1. Field of the Disclosure

The present disclosure relates to a current source circuit and an amplifier device.

### 2. Description of the Related Art

In an amplifier device for amplifying a radio-frequency signal, a bias voltage applied to an amplifier for the optimization of amplification performance is required to be stabilized.

Japanese Unexamined Patent Application Publication No. 2007-221490 discloses a bias circuit formed in a silicone (Si) IC, the bias circuit supplying a bias current to a gallium arsenide (GaAs) IC that includes an output heterojunction bipolar transistor (HBT) as an amplifier circuit. It says that changes in the amplification factor of the output HBT can be suppressed because the bias current outputted from a current mirror circuit constituting the bias circuit changes in a direction opposite to an increase or a decrease of a reference current in a reference output HBT that is provided in the GaAs IC.

The bias circuit disclosed in Japanese Unexamined Patent Application Publication No. 2007-221490 includes one current mirror circuit, but it does not have a configuration of applying the feedback to the bias current. Accordingly, the bias current tends to vary with the variations of an external power-supply voltage supplied.

Furthermore, in usage situations of general cellular phones, etc., individual transistors have characteristics providing currents increasing with a temperature rise, and the reference HBT for suppressing the variations of the bias current caused by the temperature changes also has characteristics providing a current increasing with a temperature rise. However, the bias circuit disclosed in Japanese Unexamined Patent Application Publication No. 2007-221490 does not utilize the characteristics of the reference HBT depending on temperature changes. Thus, the disclosed bias circuit cannot accurately suppress the variations of the bias current caused by temperature changes.

### BRIEF SUMMARY OF THE DISCLOSURE

In view of the above-described problems, an object of the present disclosure is to provide a current source circuit and an amplifier device each having high tolerance to the variations of an external power-supply voltage and the temperature changes.

To achieve the above object, according to one preferred embodiment of the present disclosure, there is provided a current source circuit including a power supply terminal connected to an external power supply, a first p-type transistor having a first terminal, a second terminal, and a first control terminal, a second p-type transistor having a third terminal, a fourth terminal, and a second control terminal, a first n-type transistor having a fifth terminal, a sixth terminal, and a third control terminal, a second n-type transistor having a seventh terminal, an eighth terminal, and a fourth control terminal, a third n-type transistor having a ninth terminal, a tenth terminal, and a fifth control terminal, and a resistance element connected in series between the power supply terminal and the first terminal or between the eighth terminal and a ground, wherein the second control terminal is connected to the first control terminal and the fourth terminal, the third control terminal is connected to the fourth control terminal and the fifth terminal, the fourth control terminal is connected to the fifth control terminal, the tenth terminal is connected to the ground, a first current supplied from the external power supply flows from the power supply terminal to the first terminal, from the first terminal to the second terminal, from the second terminal to the fifth terminal, from the fifth terminal to the sixth terminal, from the sixth terminal to ground, a second current supplied from the external power supply flows from the power supply terminal to the third terminal, from the third terminal to the fourth terminal, from the fourth terminal to the seventh terminal, from the seventh terminal to the eighth terminal, from the eighth terminal to ground, and the resistance element has a positive temperature coefficient and thus has a resistance value to increase with a temperature rise.

With the above features, since a current mirror circuit constituted by the first p-type transistor and the second p-type transistor and a current mirror circuit constituted by the first n-type transistor and the second n-type transistor are connected between the power supply terminal and the ground. Therefore, the first current and the second current are held in relation referring to each other, and are not affected by the variations of an external power-supply voltage.

Furthermore, since the fifth control terminal of the third n-type transistor is connected to the third control terminal of the first n-type transistor and the fourth control terminal of the second n-type transistor, a current flowing between the ninth terminal and the tenth terminal of the third n-type transistor is determined on the basis of the currents flowing through the first and second n-type transistors. Thus, the third n-type transistor operates as the so-called sink-type current source.

Since the resistance element is inserted in series, the current values of the first current and the second current can be set independently of the configurations of the individual transistors by adjusting a value of the resistance element. In other words, the current values of the first current and the second current, which are not affected by a voltage value of the external power-supply voltage, can be adjusted with only the value of the resistance element. In the case of a current circuit that is constituted just by the above-mentioned two current mirror circuits without including the resistance element, the currents flowing through the individual transistors constituting those two current mirror circuits tend to increase with a temperature rise. However, since the resistance element having the positive temperature coefficient is connected to a current path in the two current mirror circuits, the variations of the first current and the second current caused by temperature changes can be suppressed. As a result, the current source circuit having high tolerance to the variations of the external power-supply voltage and the temperature changes can be provided.

The current source circuit may include the third n-type transistor in plural number.

With the above feature, the currents not affected by the variations of the external power-supply voltage and the temperature changes can be distributed to the plurality of third n-type transistors.

The first p-type transistor, the second p-type transistor, the first n-type transistor, the second n-type transistor, and the third n-type transistor may be each a MOS (Metal-Oxide-Semiconductor) field-effect transistor.

According to another preferred embodiment of the present disclosure, there is provided a current source circuit including a power supply terminal connected to an external power supply, a first p-type transistor having a first terminal, a second terminal, and a first control terminal, a second p-type transistor having a third terminal, a fourth terminal, and a second control terminal, a first n-type transistor having a fifth terminal, a sixth terminal, and a third control terminal, a second n-type transistor having a seventh terminal, an eighth terminal, and a fourth control terminal, a third p-type transistor having an eleventh terminal, a twelfth terminal, and a sixth control terminal, and a resistance element connected in series between the power supply terminal and the first terminal or between the eighth terminal and a ground, wherein the second control terminal is connected to the first control terminal and the fourth terminal, the third control terminal is connected to the fourth control terminal and the fifth terminal, the second control terminal is connected to the sixth control terminal, the eleventh terminal is connected to the power supply terminal, a first current supplied from the external power supply flows from the power supply terminal to the first terminal, from the first terminal to the second terminal, from the second terminal to the fifth terminal, from the fifth terminal to the sixth terminal, from the sixth terminal to ground, a second current supplied from the external power supply flows from the power supply terminal to the third terminal, from the third terminal to the fourth terminal, from the fourth terminal to the seventh terminal, from the seventh terminal to the eighth terminal, from the eighth terminal to ground, and the resistance element has a positive temperature coefficient and thus has a resistance value to increase with a temperature rise.

With the above features, since a current mirror circuit constituted by the first p-type transistor and the second p-type transistor and a current mirror circuit constituted by the first n-type transistor and the second n-type transistor are connected between the power supply terminal and the ground. Therefore, the first current and the second current are held in relation referring to each other, and are not affected by the variations of an external power-supply voltage.

Furthermore, since the sixth control terminal of the third p-type transistor is connected to the first control terminal of the first p-type transistor and the second control terminal of the second p-type transistor, a current flowing between the eleventh terminal and the twelfth terminal of the third p-type transistor is determined on the basis of currents flowing through the first and second p-type transistors. Thus, the third p-type transistor operates as the so-called sourcing-type current source.

Since the resistance element is inserted in series, the current values of the first current and the second current can be set independently of the configurations of the individual transistors by adjusting a value of the resistance element. In other words, the current values of the first current and the second current, which are not affected by a voltage value of the external power-supply voltage, can be adjusted with only the value of the resistance element. In the case of a current circuit that is constituted just by the above-mentioned two current mirror circuits without including the resistance element, the currents flowing through the individual transistors constituting those two current mirror circuits tend to increase with a temperature rise. However, since the resistance element having the positive temperature coefficient is connected to a current path in the two current mirror circuits, the variations of the first current and the second current caused by temperature changes can be suppressed. As a result, the current source circuit having high tolerance to the variations of the external power-supply voltage and the temperature changes can be provided.

The current source circuit may include the third p-type transistor in plural number.

With the above feature, the currents not affected by the variations of the external power-supply voltage and the temperature changes can be distributed to the plurality of third p-type transistors.

The first p-type transistor, the second p-type transistor, the first n-type transistor, the second n-type transistor, and the third p-type transistor may be each a MOS field-effect transistor.

The first p-type transistor, the second p-type transistor, the first n-type transistor, and the second n-type transistor are each formed on or in a semiconductor substrate, and the resistance element is formed by a p-type diffusion region or an n-type diffusion region of the semiconductor substrate.

With the above feature, since the resistance element is formed in the diffusion region, it is possible for the resistance element to have the so-called positive temperature coefficient causing a resistance value to increase with a temperature rise. Furthermore, the temperature coefficient and the resistance value of the resistance element can be changed by adjusting concentration of an injected impurity. In addition, since the resistance element is formed on or in the semiconductor substrate on or in which the individual transistors are formed, the size of the current source circuit can be reduced.

The current source circuit may further include a fourth p-type transistor having a seventh control terminal to which a first bias voltage is applied, the fourth p-type transistor being disposed between the first terminal and the second terminal and cascode-connected to the first p-type transistor, or a fifth p-type transistor having an eighth control terminal to which the first bias voltage is applied, the fifth p-type transistor being disposed between the third terminal and the fourth terminal and cascode-connected to the second p-type transistor, or both of the fourth p-type transistor and the fifth p-type transistor.

With the above feature, the first current can be made less susceptible to voltage changes at the second terminal side of the first p-type transistor, and the second current can be made less susceptible to voltage changes at the fourth terminal side of the second p-type transistor. Hence the tolerance to the variations of the power supply voltage can be further enhanced.

The current source circuit may further include a fourth n-type transistor having a ninth control terminal to which a second bias voltage is applied, the fourth n-type transistor being disposed between the fifth terminal and the sixth terminal and cascode-connected to the first n-type transistor, or a fifth n-type transistor having a tenth control terminal to which the second bias voltage is applied, the fifth n-type transistor being disposed between the seventh terminal and the eighth terminal and cascode-connected to the second n-type transistor, or both of the fourth n-type transistor and the fifth n-type transistor.

With the above feature, the first current can be made less susceptible to voltage changes at the fifth terminal side of the first n-type transistor, and the second current can be made less susceptible to voltage changes at the seventh terminal side of the second n-type transistor. Hence the tolerance to the variations of the power supply voltage can be further enhanced.

According to still another preferred embodiment of the present disclosure, there is provided an amplifier device including one of the above-described current source circuits, wherein the amplifier device includes a bias supply circuit constituted by the first p-type transistor, the second p-type transistor, the first n-type transistor, the second n-type transistor, and the resistance element, the bias supply circuit generating a bias voltage, and an amplifier circuit including the third n-type transistor in which a radio-frequency input signal and the bias voltage are applied to the fifth control terminal.

With the above features, since the current source not affected by the variations of the external power-supply voltage and the temperature changes can be constituted in the bias supply circuit, the amplifier device having high tolerance to the variations of the external power-supply voltage and the temperature changes can be provided.

According to still another preferred embodiment of the present disclosure, there is provided an amplifier device including one of the above-described current source circuits, wherein the amplifier device includes a bias supply circuit constituted by the first p-type transistor, the second p-type transistor, the first n-type transistor, the second n-type transistor, and the resistance element, the bias supply circuit generating a bias voltage, and an amplifier circuit including the third p-type transistor in which a radio-frequency input signal and the bias voltage are applied to the sixth control terminal.

With the above features, since the current source not affected by the variations of the external power-supply voltage and the temperature changes can be constituted in the bias supply circuit, the amplifier device having high tolerance to the variations of the external power-supply voltage and the temperature changes can be provided.

Other features, elements, characteristics and advantages of the present disclosure will become more apparent from the following detailed description of preferred embodiments of the present disclosure with reference to the attached drawings.

### BRIEF DESCRIPTION OF THE SEVERAL VIEWS OF THE DRAWINGS

FIG. 1 is a circuit diagram of a current source circuit according to a first embodiment;

FIG. 2 is an explanatory view referenced to explain an operation of the current source circuit according to the first embodiment;

FIG. 3 is a graph depicting the temperature characteristics of a resistance element according to the first embodiment;

FIG. 4A is a graph depicting the temperature characteristics of a current source circuit according to a comparative example;

FIG. 4B is a graph depicting the temperature characteristics of the current source circuit according to the first embodiment;

FIG. 5 is a circuit diagram of a current source circuit according to a modification of the first embodiment;

FIG. 6 is a circuit diagram of a current source circuit according to a second embodiment;

FIG. 7 is a circuit diagram of a current source circuit according to a modification of the second embodiment;

FIG. 8 is a circuit diagram of a current source circuit according to a third embodiment;

FIG. 9 is a circuit diagram of a current source circuit according to a fourth embodiment;

FIG. 10 is a graph depicting the variation characteristics of a reference current with respect to a power supply voltage in the current source circuit according to the fourth embodiment; and

FIG. 11 is a circuit diagram of an amplifier device according to a fifth embodiment.

### DETAILED DESCRIPTION OF THE DISCLOSURE

Practical examples of the present disclosure will be described in detail below with reference to the embodiments and drawings. It is to be noted that any of the following embodiments represents a generic or specific example. Numerical values, shapes, materials, constituent elements, arrangements and connection forms of the constituent elements, etc., which are described in the following embodiments, are merely illustrative, and they are not purported to limit the scope of the present disclosure. Among the constituent elements in the following embodiments, those ones not stated in independent claims are explained as optional constituent elements. Sizes or relative size ratios of the constituent elements illustrated in the drawings are not always exactly true in a strict sense.

### First Embodiment

### 1.1 Configuration of Current Source Circuit

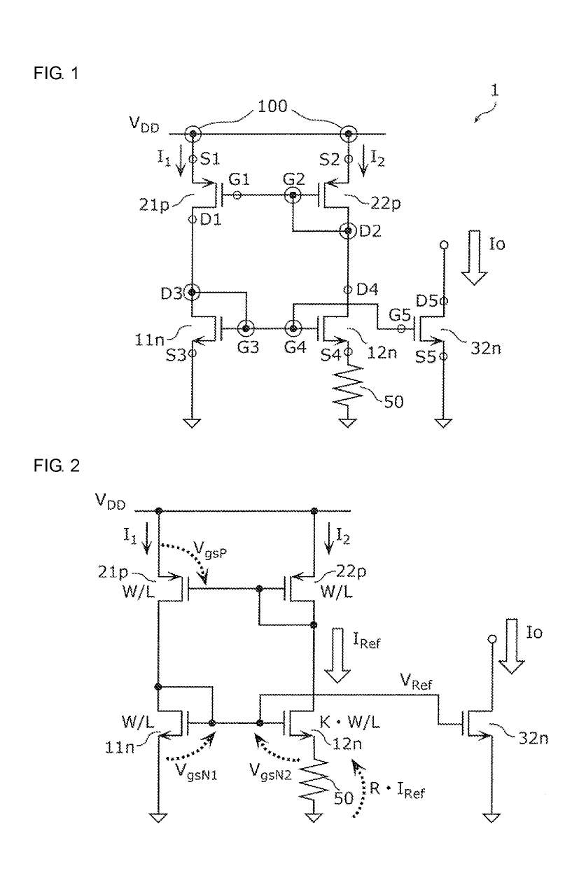

FIG. 1 is a circuit diagram of a current source circuit 1 according to a first embodiment. As illustrated in FIG. 1, the current source circuit 1 includes a power supply terminal 100, p-type transistors 21p and 22p, n-type transistors 11n and 12n, an output n-type transistor 32n, and a resistance element 50.

The power supply terminal 100 is a terminal connected to an external power supply and used to apply a power supply voltage V_{DD} to the current source circuit 1.

The p-type transistor 21p is a first p-type transistor having a source terminal S1 (first terminal), a drain terminal D1 (second terminal), and a gate terminal G1 (first control terminal).

The p-type transistor 22p is a second p-type transistor having a source terminal S2 (third terminal), a drain terminal D2 (fourth terminal), and a gate terminal G2 (second control terminal).

The n-type transistor 11n is a first n-type transistor having a drain terminal D3 (fifth terminal), a source terminal S3 (sixth terminal), and a gate terminal G3 (third control terminal).

The n-type transistor 12n is a second n-type transistor having a drain terminal D4 (seventh terminal), a source terminal S4 (eighth terminal), and a gate terminal G4 (fourth control terminal).

The output n-type transistor 32n is a third n-type transistor having a drain terminal D5 (ninth terminal), a source terminal S5 (tenth terminal), and a gate terminal G5 (fifth control terminal).

The above-mentioned transistors are each constituted by a MOSFET (Metal-Oxide-Semiconductor Field-Effect-Transistor), for example. Alternatively, the above-mentioned transistors may be each a bipolar transistor having a base, an emitter, and a collector.

The resistance element 50 is connected in series between the source terminal S4 and a ground, and it has the so-called positive temperature coefficient causing a resistance value R to increase with a temperature rise.

The gate terminal G2 is connected to the gate terminal G1 and the drain terminal D2. The gate terminal G3 is connected to the gate terminal G4 and the drain terminal D3. The gate terminal G4 is connected to the gate terminal G5. The source terminal S5 is connected to the ground.

A current I₁ (first current) supplied from the external power supply via the power supply terminal 100 flows from the power supply terminal 100 to the source terminal S1, from the source terminal Si to the drain terminal D1, from the drain terminal D1 to the drain terminal D3, from the drain terminal D3 to the source terminal S3, from the source terminal S3 to the ground. In other words, the current I₁ flows in sequence of the power supply terminal 100, the source terminal S1, the drain terminal D1, the drain terminal D3, the source terminal S3, and the ground. A current I₂ (second current) supplied from the external power supply via the power supply terminal 100 flows from the power supply terminal 100 to the source terminal S2, from the source terminal S2 to the drain terminal D2, from the drain terminal D2 to the drain terminal D4, from the drain terminal D4 to the source terminal S4, from the source terminal S4 to the resistance element 50, from the resistance element 50 to the ground. In other words, the current I₂ flows in sequence of the power supply terminal 100, the source terminal S2, the drain terminal D2, the drain terminal D4, the source terminal S4, the resistance element 50, and the ground.

With the circuit configuration described above, a current mirror circuit constituted by the p-type transistors 21p and 22p and a current mirror circuit constituted by the n-type transistors 11n and 12n are connected between the power supply terminal 100 and the ground. Therefore, the current source circuit 1 has a feedback configuration in combination of the two current mirror circuits such that the current I₂ becomes a current copying the current I₁ and both the currents I₁ and I₂ refer to each other. Thus, those currents are less affected by the variations of the power supply voltage V_{DD}.

Furthermore, since the gate terminal G5 of the output n-type transistor 32n is connected to the gate terminal G3 of the n-type transistor 11n and the gate terminal G4 of the n-type transistor 12n, a current Io flowing between the drain terminal D5 and the source terminal S5 of the output n-type transistor 32n is determined on the basis of the currents flowing through the n-type transistor 11n and the n-type transistor 12n. Thus, the output n-type transistor 32n serves as the so-called sink-type current source.

Moreover, since the resistance element 50 is inserted in series between the source terminal S4 and the ground, the current values of the current I₁ and the current I₂ can be set independently of parameters, such as channel lengths (L) and channel widths (W) of the individual transistors, by adjusting a value of the resistance element 50. In other words, the current values of the current I₁ and the current I₂, which are not affected by the voltage value of the power supply voltage V_{DD}, can be adjusted with only the value of the resistance element 50. In the case of a current circuit that is constituted just by the above-mentioned two current mirror circuits without including the resistance element 50, the currents flowing through the individual transistors constituting those two current mirror circuits increase with a temperature rise. On the other hand, in this embodiment, the resistance element 50 having the positive temperature coefficient is connected to a current path in the two current mirror circuits. Thus, the current flowing in each of the two current mirror circuits has the positive temperature coefficient, whereas a current flowing through the resistance element 50 has a negative temperature coefficient. As a result, the variations of the current I₁ and the current I₂ caused by temperature changes can be suppressed.

It is hence possible to provide the current source circuit 1 having high tolerance to the variations of the external power-supply voltage and the temperature changes.

The point that the current source circuit 1 according to this embodiment has high tolerance to the variations of the external power-supply voltage and the temperature changes will be described in more detail below.

### 1.2 Tolerance to Variations of Power Supply Voltage and Temperature Changes

FIG. 2 is an explanatory view referenced to explain an operation of the current source circuit 1 according to the first embodiment. In the current source circuit 1, the p-type transistors 21p and 22p constitute the current mirror circuit such that the current I₁ and the current I₂ become equal to each other.

Furthermore, a gate-source voltage V_{gsN1} is generated as corresponding to the current I₁ flowing through the n-type transistor 11n. Although a gate potential of the n-type transistor 12n is equal to that of the n-type transistor 11n, a gate-source voltage V_{gSN2} of the n-type transistor 12n is smaller than the gate-source voltage V_{gsN1} of the n-type transistor 11n because the resistance element 50 is present between the source terminal S4 of the n-type transistor 12n and the ground.

The n-type transistor 12n is formed in a K-time size in comparison with the n-type transistor 11n. Even with the gate-source voltage V_{gSN2} being relatively small, therefore, a current equal to that flowing through the n-type transistor 11n can be caused to flow through the n-type transistor 12n. An actual value of the current is uniquely determined depending on K and the resistance value R.

Thus, the current flowing in the current source circuit 1 represents an equilibrium current in a state of the individual components having reached equilibrium, and the equilibrium current can be adjusted depending on the resistance value R. The value of the equilibrium current is called a reference current I_{ref} when the current source circuit 1 operates as a constant current source.

When the current I₂ increases in comparison with the reference current I_{ref} due to influences such as a disturbance, the current I₁ also increases by the action of the current mirror circuit constituted by the p-type transistors 21p and 22p. At that time, since an increase amount of a voltage (R×I₂) across the resistance element 50 is larger than that of the gate-source voltage V_{gsN1} of the n-type transistor 11n, the gate-source voltage V_{gSN2} of the n-type transistor 12n reduces consequently. In other words, the current I₂ flowing through the p-type transistor 22p reduces. Conversely, when the current I₂ reduces in comparison with the reference current I_{ref}, the gate-source voltage V_{gSN2} turns toward an increasing direction. As a result, the current I₂ behaves in a way of remaining at the reference current I_{ref} having a constant value. From the above discussion, it can be qualitatively understood that the reference current I_{ref} flowing in the current source circuit 1 is stabilized to a value which is determined depending on the size ratio K of the n-type transistor 11n to the n-type transistor 12n and the resistance value R of the resistance element 50.

The reference current I_{ref} is quantitatively analyzed here. Because the gate potentials of both the n-type transistors 11n and 12n are equal to each other, the gate-source voltage V_{gsN1} of the n-type transistor 11n, the gate-source voltage V_{gSN2} of the n-type transistor 12n, and the resistance value R of the resistance element 50 satisfy the following relation expressed by Eq. 1.

V_{gsN1}=V_{gsN2}+I_{ref}·R (Eq. 1)

The gate-source voltages V_{gsN1} and V_{gSN2} are expressed by the following Eq. 2 and Eq. 3, respectively.

$$\begin{matrix}{V}_{gsN 1} = \sqrt{\frac{2 {I}_{ref}}{μ {C}_{OX} W \text{/} L}} + {Vt}_{N 1} & ( Eq . 2 ) \\ {V}_{gsN 2} = \sqrt{\frac{2 {I}_{ref}}{μ {C}_{OX} K \cdot W \text{/} L}} + {Vt}_{N 2} & ( Eq . 3 )\end{matrix}$$

Here, L denotes a channel length of the n-type transistor 11n, and W denotes a channel width of the n-type transistor 11n. Furthermore, μ denotes an electron moving speed, and C_{OX} denotes an equivalent capacitance density of each of the n-type transistors 11n and 12n. Vt_{N1} denotes a threshold voltage of the n-type transistor 11n, and Vt_{N2} denotes a threshold voltage of the n-type transistor 12n.

The following Eq. 4 is derived by substituting Eq. 2 and Eq. 3 into Eq. 1.

$$\sqrt{\frac{2 {I}_{ref}}{μ {C}_{OX} W \text{/} L}} + {Vt}_{N 1} = \sqrt{\frac{2 {I}_{ref}}{μ {C}_{OX} K \cdot W \text{/} L}} + {Vt}_{N 2} + {I}_{ref} \cdot R \qquad ( Eq . 4 )$$

The following Eq. 5 is derived by solving Eq. 4 in terms of the reference current I_{ref} on an assumption that the threshold voltage Vt_{N1} of the n-type transistor 11n and the threshold voltage Vt_{N2} of the n-type transistor 12n are equal.

$${I}_{ref} = \frac{1}{{R}^{2}} {( 1 - \frac{1}{\sqrt{K}} )}^{2} \cdot \frac{2}{μ {C}_{OX} W \text{/} L} \qquad ( Eq . 5 )$$

From Eq. 5, it is understood that the reference current I_{ref} takes a value not depending on the power supply voltage V_{DD}.

From Eq. 5, it is further understood that the reference current I_{ref} depends on the resistance value R of the resistance element 50 and decreases as the resistance value R increases.

As described above, the current flowing through each of the transistors constituting the current source circuit 1 has a tendency to increase with a temperature rise at least in a temperature range (e.g., about −30° C. to 90° C.) near the room temperature. Thus, the current generated in each of the above-mentioned first and second current mirror circuits has the so-called positive temperature coefficient causing the current to increase with a temperature rise.

On the other hand, the resistance element 50 in the current source circuit 1 according to this embodiment has the so-called positive temperature coefficient causing a resistance value to increase with a temperature rise. Accordingly, an increase of the current generated in each of the two current mirror circuits depending on the temperature rise can be cancelled on the basis of not only the fact that the resistance value R of the resistance element 50 increases with a temperature rise, but also the relation of Eq. 5.

Hence the current source circuit 1 having high tolerance to the variations of the external power-supply voltage and the temperature changes can be provided.

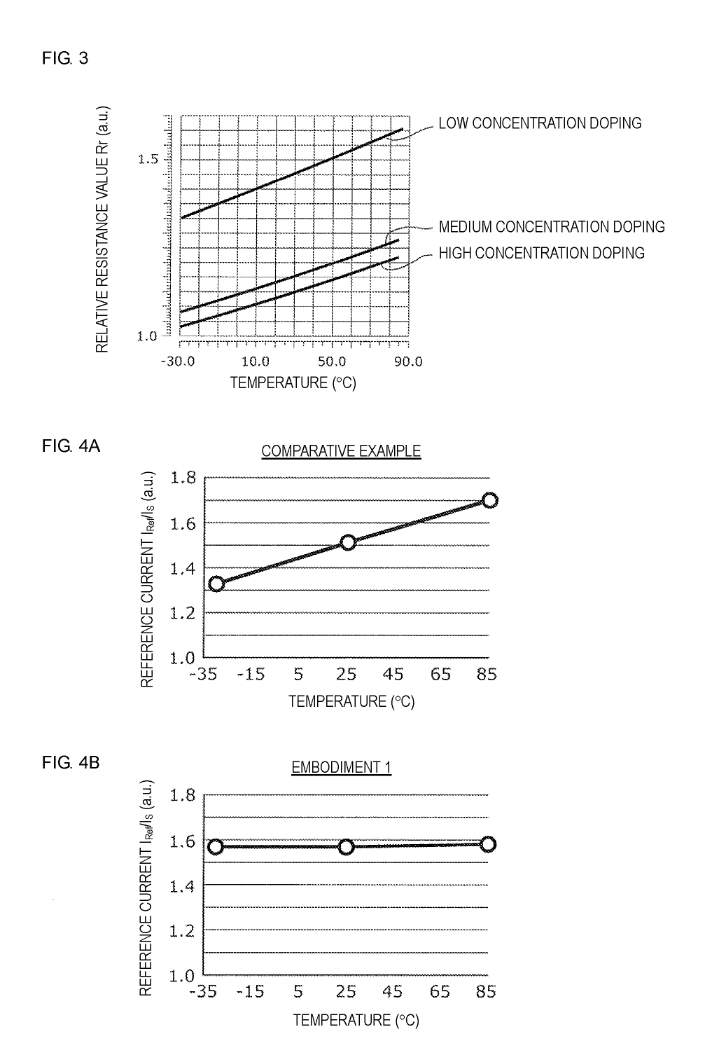

FIG. 3 is a graph depicting the temperature characteristics of the resistance element 50 according to the first embodiment. FIG. 3 represents the temperature characteristics of a relative resistance value Rr resulting from normalizing the resistance value R of the resistance element 50 on the basis of a predetermined resistance value. As seen from FIG. 3, the resistance value R of the resistance element 50 (relative resistance value Rr in FIG. 3) has the so-called positive temperature coefficient causing the resistance value to increase with a temperature rise. The resistance element 50 is formed, for example, in a p-type diffusion region or an n-type diffusion region of a Si semiconductor substrate or a GaAs semiconductor substrate on or in which the p-type transistors 21p and 22p and the n-type transistors 11n and 12n are formed. Furthermore, as seen from FIG. 3, as an impurity concentration of the diffusion region increases, the diffusion region is metallized at a higher degree. In other words, as an impurity concentration of the diffusion region increases, the resistance value R (relative resistance value Rr in FIG. 3) reduces, and a temperature coefficient defined as a change rate of the resistance value R (relative resistance value Rr in FIG. 3) relative to temperature change also reduces. Thus, the resistance value R and the temperature coefficient of the resistance element 50 can be adjusted by adjusting the impurity concentration of the diffusion region. Moreover, since the resistance element 50 is formed on or in a semiconductor substrate on or in which the above-described transistors are formed, or in a Si IC or a GaAs IC in which the above-described transistor are integrated, the size of the current source circuit 1 can be reduced.

FIG. 4A is a graph depicting the temperature characteristics of a current source circuit according to a comparative example. FIG. 4B is a graph depicting the temperature characteristics of the current source circuit 1 according to the first embodiment. The current source circuit according to the comparative example is different from the current source circuit 1 according to the first embodiment only in that a resistance element has a resistance value not changed depending on a temperature rise. In other words, the temperature coefficient of the resistance element in the current source circuit according to the comparative example is zero.

In the graphs of FIGS. 4A and 4B, the vertical axis indicates a relative reference current resulting from normalizing the reference current I_{ref} on the basis of a predetermined fixed current I_{S}.

As seen from FIG. 4A, in the current source circuit according to the comparative example, the reference current I_{ref} (relative reference current I_{ref} in FIG. 4A) increases with a temperature rise. Those temperature characteristics reflect the fact that the current generated in each of the two current mirror circuits constituting the current source circuit according to the comparative example has the so-called positive temperature coefficient causing the current to increase with a temperature rise.

On the other hand, as seen from FIG. 4B, in the current source circuit 1 according to this embodiment, the reference current I_{ref} (relative reference current I_{ref} in FIG. 4B) has characteristics not changing depending on the temperature changes. Those temperature characteristics are attributable to the fact that the resistance element 50 has the so-called positive temperature coefficient causing the resistance value to increase with a temperature rise. As a result, the increase of the current generated in each of the two current mirror circuits depending on the temperature rise is cancelled.

### 1.3 Configuration of Current Source Circuit According to Modification

FIG. 5 is a circuit diagram of a current source circuit 2 according to a modification of the first embodiment. As illustrated in FIG. 5, the current source circuit 2 includes a power supply terminal 100, p-type transistors 21p and 22p, n-type transistors 11n and 12n, output n-type transistors 32n1, 32n2 and 32n3, and a resistance element 50. The current source circuit 2 according to this modification is different from the current source circuit 1 according to the first embodiment only in including a plurality of output n-type transistors. In the following, the current source circuit 2 according to this modification is described mainly about the different points while the description of the same points as those in the current source circuit 1 according to the first embodiment is omitted.

The output n-type transistor 32n1 is a third n-type transistor having a drain terminal D51 (ninth terminal), a source terminal S51 (tenth terminal), and a gate terminal G51 (fifth control terminal). The output n-type transistor 32n2 is a third n-type transistor having a drain terminal D52 (ninth terminal), a source terminal S52 (tenth terminal), and a gate terminal G52 (fifth control terminal). The output n-type transistor 32n3 is a third n-type transistor having a drain terminal D53 (ninth terminal), a source terminal S53 (tenth terminal), and a gate terminal G53 (fifth control terminal).

Although this modification represents the configuration including the three output n-type transistors 32n1 to 32n3, the current source circuit is just required to include two or more output n-type transistors.

In short, the current source circuit 2 according to this modification includes the plurality of output n-type transistors. Therefore, the currents (Iₒ₁, Iₒ₂ and Iₒ₃ in FIG. 5) not affected by the variations of the power supply voltage V_{DD} and the temperature changes can be distributed to the plurality of output n-type transistors.

### Second Embodiment

While the current source circuit 1 according to the first embodiment is a circuit of current sink type generating the reference current I_{ref} by an n-type transistor, a second embodiment is described in connection with a circuit of current sourcing type generating the reference current I_{ref} by a p-type transistor.

### 2.1 Configuration of Current Source Circuit

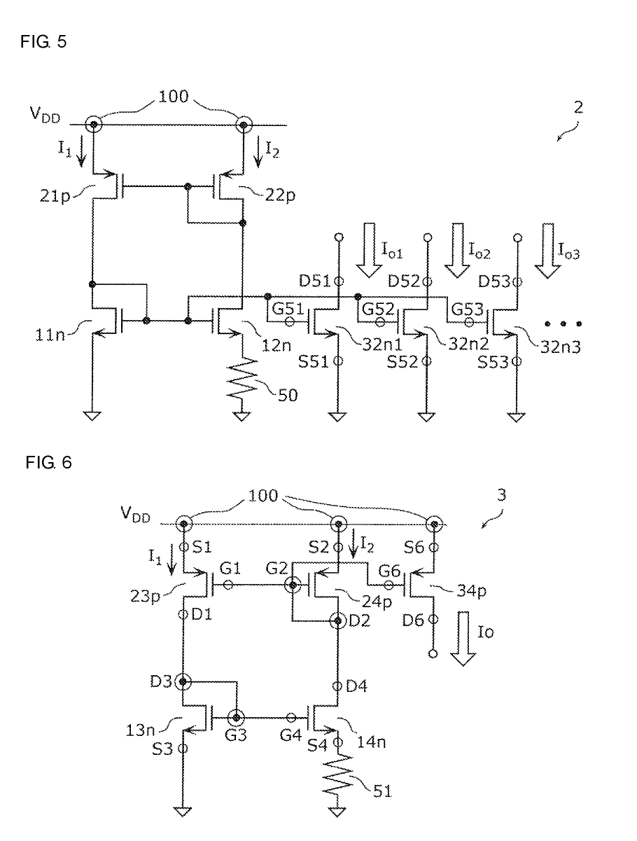

FIG. 6 is a circuit diagram of a current source circuit 3 according to the second embodiment. As illustrated in FIG. 6, the current source circuit 3 includes a power supply terminal 100, p-type transistors 23p and 24p, n-type transistors 13n and 14n, an output p-type transistor 34p, and a resistance element 51. The current source circuit 3 according to the second embodiment is different from the current source circuit 1 according to the first embodiment in the connection configuration of the output p-type transistor 34p. In the following, the current source circuit 3 according to the second embodiment is described mainly about the different points while the description of the same points as those in the current source circuit 1 according to the first embodiment is omitted.

The p-type transistor 23p is a first p-type transistor having a source terminal S1 (first terminal), a drain terminal D1 (second terminal), and a gate terminal G1 (first control terminal).

The p-type transistor 24p is a second p-type transistor having a source terminal S2 (third terminal), a drain terminal D2 (fourth terminal), and a gate terminal G2 (second control terminal).

The n-type transistor 13n is a first n-type transistor having a drain terminal D3 (fifth terminal), a source terminal S3 (sixth terminal), and a gate terminal G3 (third control terminal).

The n-type transistor 14n is a second n-type transistor having a drain terminal D4 (seventh terminal), a source terminal S4 (eighth terminal), and a gate terminal G4 (fourth control terminal).

The output p-type transistor 34p is a third p-type transistor having a source terminal S6 (eleventh terminal), a drain terminal D6 (twelfth terminal), and a gate terminal G6 (sixth control terminal).

The above-mentioned transistors are each constituted by a MOS field-effect transistor, for example. Alternatively, the above-mentioned transistors may be each a bipolar transistor having a base, an emitter, and a collector.

The resistance element 51 is connected in series between the source terminal S4 and a ground, and it has a positive temperature coefficient causing a resistance value to increase with a temperature rise.

The gate terminal G2 is connected to the gate terminal G6. The source terminal S6 is connected to the power supply terminal 100.

With the circuit configuration described above, a current mirror circuit constituted by the p-type transistors 23p and 24p and a current mirror circuit constituted by the n-type transistors 13n and 14n are connected between the power supply terminal 100 and the ground. Therefore, the current source circuit 3 has a feedback configuration in combination of the two current mirror circuits such that the current I₂ becomes a current copying the current I₁ and both the currents I₁ and I₂ have the same current value. Thus, those currents are less affected by the variations of the power supply voltage V_{DD}.

Furthermore, since the gate terminal G6 of the output p-type transistor 34p is connected to the gate terminal G1 of the p-type transistor 23p and the gate terminal G2 of the p-type transistor 24p, a current Io flowing between the source terminal S6 and the drain terminal D6 of the output p-type transistor 34p constitutes the so-called sourcing-type current source.

Moreover, since the resistance element 51 is inserted in series between the source terminal S4 and the ground, the current values of the current I₁ and the current I₂ can be set independently of parameters, such as channel lengths (L) and channel widths (W) of the individual transistors, by adjusting a value of the resistance element 51. In other words, the current values of the current I₁ and the current I₂, which are not affected by the voltage value of the power supply voltage V_{DD}, can be adjusted with only the value of the resistance element 51. In the case of a current circuit that is constituted just by the above-mentioned two current mirror circuits without including the resistance element 51, the currents flowing through the individual transistors constituting those two current mirror circuits increase with a temperature rise. On the other hand, in this embodiment, the resistance element 51 having the positive temperature coefficient is connected to a current path in the two current mirror circuits. Thus, the current flowing in each of the two current mirror circuits has the positive temperature coefficient, whereas a current flowing through the resistance element 51 has a negative temperature coefficient. As a result, the variations of the current I₁ and the current I₂ caused by temperature changes can be suppressed.

It is hence possible to provide the current source circuit 3 having high tolerance to the variations of the external power-supply voltage and the temperature changes.

In the current source circuit 3, since the resistance element 51 is connected to the n-type transistor 14n, the reference current I_{ref} in this circuit is determined depending on a size ratio K of the n-type transistor 13n to the n-type transistor 14n and the resistance value R of the resistance element 51. A value of the reference current I_{ref} is expressed by above Eq. 5 as with the reference current I_{ref} in the current source circuit 1. Thus, it is understood that the reference current I_{ref} does not depend on the power supply voltage V_{DD}.

Moreover, an increase of the current generated in each of the two current mirror circuits depending on the temperature rise can be cancelled on the basis of not only the fact that the resistance value R of the resistance element 51 increases with a temperature rise, but also the relation of Eq. 5.

Hence the current source circuit 3 having high tolerance to the variations of the external power-supply voltage and the temperature changes can be provided.

### 2.2 Configuration of Current Source Circuit According to Modification

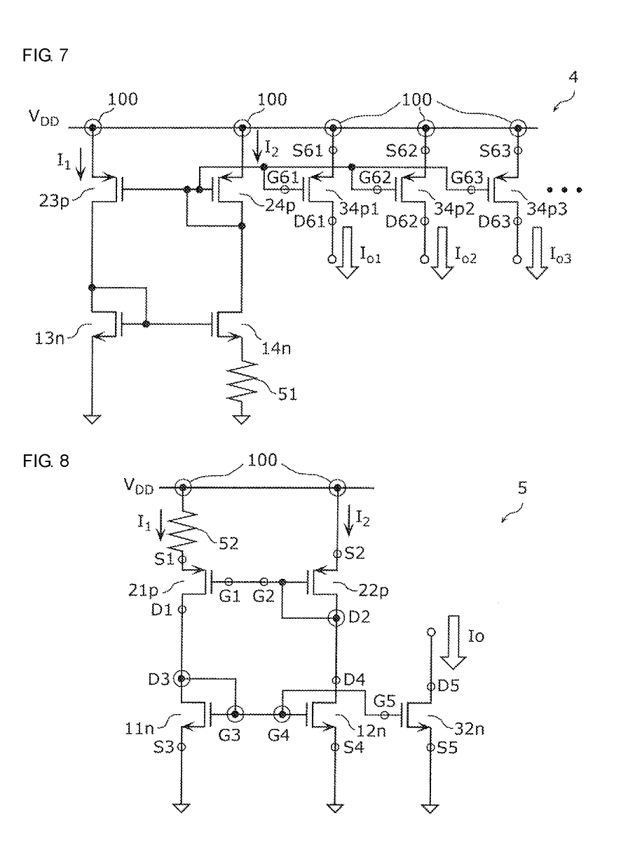

FIG. 7 is a circuit diagram of a current source circuit 4 according to a modification of the second embodiment. As illustrated in FIG. 7, the current source circuit 4 includes a power supply terminal 100, p-type transistors 23p and 24p, n-type transistors 13n and 14n, output p-type transistors 34p1, 34p2 and 34p3, and a resistance element 51. The current source circuit 4 according to this modification is different from the current source circuit 3 according to the second embodiment only in including a plurality of output p-type transistors. In the following, the current source circuit 4 according to this modification is described mainly about the different points while the description of the same points as those in the current source circuit 3 according to the second embodiment is omitted.

The output p-type transistor 34p1 is a third p-type transistor having a source terminal S61 (eleventh terminal), a drain terminal D61 (twelfth terminal), and a gate terminal G61 (sixth control terminal). The output p-type transistor 34p2 is a third p-type transistor having a source terminal S62 (eleventh terminal), a drain terminal D62 (twelfth terminal), and a gate terminal G62 (sixth control terminal). The output p-type transistor 34p3 is a third p-type transistor having a source terminal S63 (eleventh terminal), a drain terminal D63 (twelfth terminal), and a gate terminal G63 (sixth control terminal).

Although this modification represents the configuration including the three output p-type transistors 34p1 to 34p3, the current source circuit is just required to include two or more output p-type transistors.

In short, the current source circuit 4 according to this modification includes the plurality of output p-type transistors. Therefore, the currents (Iₒ₁, Iₒ₂ and Iₒ₃ in FIG. 7) not affected by the variations of the power supply voltage V_{DD} and the temperature changes can be distributed to the plurality of output p-type transistors.

### Third Embodiment

A third embodiment will be described below in connection with a current source circuit that is different in layout of the resistance element from the current source circuit 1 according to the first embodiment and the current source circuit 3 according to the second embodiment.

### 3.1 Configuration of Current Source Circuit

FIG. 8 is a circuit diagram of a current source circuit 5 according to the third embodiment. As illustrated in FIG. 8, the current source circuit 5 includes a power supply terminal 100, p-type transistors 21p and 22p, n-type transistors 11n and 12n, an output n-type transistor 32n, and a resistance element 52. The current source circuit 5 according to the third embodiment is different from the current source circuit 1 according to the first embodiment in the connection configuration of the resistance element 52. In the following, the current source circuit 5 according to the third embodiment is described mainly about the different points while the description of the same points as those in the current source circuit 1 according to the first embodiment is omitted.

The resistance element 52 is connected in series between the power supply terminal 100 and the source terminal Si (first terminal) of the p-type transistor 21p, and it has a positive temperature coefficient causing a resistance value to increase with a temperature rise.

With the circuit configuration described above, a current mirror circuit constituted by the p-type transistors 21p and 22p and a current mirror circuit constituted by the n-type transistors 11n and 12n are connected between the power supply terminal 100 and the ground. Therefore, the current source circuit 5 has a feedback configuration in combination of the two current mirror circuits such that the current I₂ becomes a current copying the current I₁ and both the currents I₁ and I₂ have the same current value. Thus, those currents are less affected by the variations of the power supply voltage V_{DD}.

Furthermore, since the gate terminal G5 of the output n-type transistor 32n is connected to the gate terminal G3 of the n-type transistor 11n and the gate terminal G4 of the n-type transistor 12n, a current Io flowing between the drain terminal D5 and the source terminal S5 of the output n-type transistor 32n is determined on the basis of the currents flowing through the n-type transistor 11n and the n-type transistor 12n. Thus, the output n-type transistor 32n operates as the so-called sink-type current source.

Moreover, since the resistance element 52 is inserted in series between the power supply terminal 100 and the source terminal S1, the current values of the current I₁ and the current I₂ can be set independently of parameters, such as channel lengths (L) and channel widths (W) of the individual transistors, by adjusting a value of the resistance element 52. In other words, the current values of the current I₁ and the current I₂ can be set without being affected by the voltage value of the power supply voltage V_{DD}. In the case of a current circuit that is constituted just by the above-mentioned two current mirror circuits without including the resistance element 52, the currents flowing through the individual transistors constituting those two current mirror circuits increase with a temperature rise. On the other hand, in this embodiment, the resistance element 52 having the positive temperature coefficient is connected to a current path in the two current mirror circuits. Thus, the current flowing in each of the two current mirror circuits has the positive temperature coefficient, whereas a current flowing through the resistance element 52 has a negative temperature coefficient. As a result, the variations of the current I₁ and the current I₂ caused by temperature changes can be suppressed.

It is hence possible to provide the current source circuit 5 having high tolerance to the variations of the external power-supply voltage and the temperature changes.

### 3.2 Tolerance to Variations of Power Supply Voltage and Temperature Changes

In the current source circuit 5, since the resistance element 52 is connected to the p-type transistor 21p, the reference current I_{ref} in this circuit is determined depending on a size ratio K of the p-type transistor 21p to the p-type transistor 22p and a resistance value R of the resistance element 52. A value of the reference current I_{ref} is expressed by the following Eq. 6 on the basis of a similar consideration to that regarding the reference current I_{ref} in the current source circuit 1.

V_{gsP2}=V_{gsP1}+I_{ref}·R (Eq. 6)

Furthermore, a gate-source voltage V_{gsP1} of the p-type transistor 21p and a gate-source voltage V_{gsP2} of the p-type transistor 22p are expressed similarly to Eq. 3 and Eq. 2, respectively. Moreover, Eq. 5 is derived as in the current source circuit 1 according to the first embodiment on an assumption that a threshold voltage Vt_{P1} of the p-type transistor 21p and a threshold voltage Vt_{P2} of the p-type transistor 22p are equal.

From Eq. 5, it is understood that the reference current I_{ref} takes a value not depending on the power supply voltage V_{DD}.

From Eq. 5, it is further understood that the reference current I_{ref} depends on the resistance value R of the resistance element 52 and decreases as the resistance value R increases.

As described above, the current flowing through each of the transistors constituting the current source circuit 5 has a tendency to increase with a temperature rise at least in a temperature range (e.g., about −30° C. to 90° C.) near the room temperature. Thus, the current generated in each of the two current mirror circuits has the so-called positive temperature coefficient causing the current to increase with a temperature rise.

On the other hand, the resistance element 52 in the current source circuit 5 according to this embodiment has the so-called positive temperature coefficient causing a resistance value to increase with a temperature rise. Accordingly, an increase of the current generated in each of the two current mirror circuits depending on the temperature rise can be cancelled on the basis of not only the fact that the resistance value R of the resistance element 52 increases with a temperature rise, but also the relation of Eq. 5.

Hence the current source circuit 5 having high tolerance to the variations of the external power-supply voltage and the temperature changes can be provided.

A current source circuit according to a first modification of this embodiment may be constituted by modifying the circuit configuration of the current source circuit 3 according to the second embodiment such that the resistance element 51 is connected in series between the power supply terminal 100 and the source terminal Si of the p-type transistor 23p instead of being connected in series between the source terminal S4 of the n-type transistor 14n and the ground. Such a configuration can also provide similar advantageous effects to those obtained with the current source circuit 5 according to this embodiment.

A current source circuit according to a second modification of this embodiment may include the plurality of output n-type transistors 32n as in the current source circuit 2 according to the modification of the first embodiment, or may include the plurality of output p-type transistors 34p as in the current source circuit 4 according to the modification of the second embodiment. With those configurations, the currents not affected by the variations of the power supply voltage V_{DD} and the temperature changes can be distributed to the plurality of output n-type transistors or output p-type transistors.

### Fourth Embodiment

A current source circuit according to a fourth embodiment has a configuration in which a p-type transistor or an n-type transistor is cascode-connected to each of the p-type transistors and the n-type transistors constituting the two current mirror circuits.

### 4.1 Configuration of Current Source Circuit

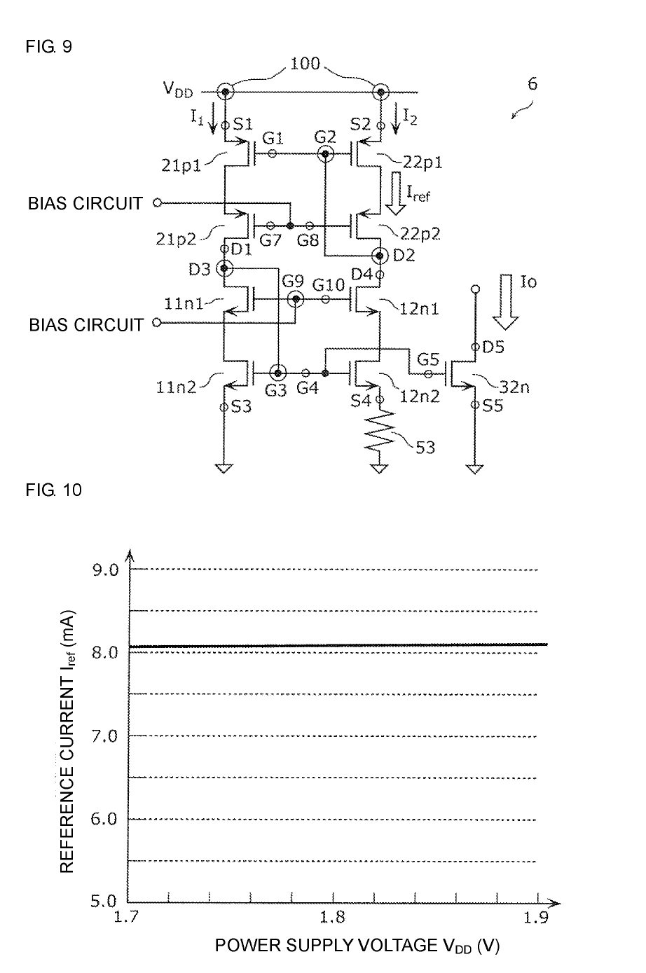

FIG. 9 is a circuit diagram of a current source circuit 6 according to the fourth embodiment. As illustrated in FIG. 9, the current source circuit 6 includes a power supply terminal 100, p-type transistors 21p1, 21p2, 22p1 and 22p2, n-type transistors 11n1, 11n2, 12n1 and 12n2, an output n-type transistor 32n, and a resistance element 53. The current source circuit 6 according to the fourth embodiment is different from the current source circuit 1 according to the first embodiment in configuration of the p-type transistors and the n-type transistor. In the following, the current source circuit 6 according to the fourth embodiment is described mainly about the different points while the description of the same points as those in the current source circuit 1 according to the first embodiment is omitted.

The p-type transistor 21p1 is a first p-type transistor having a source terminal S1 (first terminal), a drain terminal D1 (second terminal), and a gate terminal G1 (first control terminal).

The p-type transistor 22p1 is a second p-type transistor having a source terminal S2 (third terminal), a drain terminal D2 (fourth terminal), and a gate terminal G2 (second control terminal).

The n-type transistor 11n2 is a first n-type transistor having a drain terminal D3 (fifth terminal), a source terminal S3 (sixth terminal), and a gate terminal G3 (third control terminal).

The n-type transistor 12n2 is a second n-type transistor having a drain terminal D4 (seventh terminal), a source terminal S4 (eighth terminal), and a gate terminal G4 (fourth control terminal).

The output n-type transistor 32n is a third n-type transistor having a drain terminal D5 (ninth terminal), a source terminal S5 (tenth terminal), and a gate terminal G5 (fifth control terminal).

The resistance element 53 is connected in series between the source terminal S4 and a ground, and it has a positive temperature coefficient causing a resistance value to increase with a temperature rise.

The gate terminal G2 is connected to the gate terminal G1 and the drain terminal D2. The gate terminal G3 is connected to the gate terminal G4 and the drain terminal D3. The gate terminal G4 is connected to the gate terminal G5. The source terminal S5 is connected to the ground.

A current I₁ (first current) supplied from the external power supply via the power supply terminal 100 flows in sequence of the power supply terminal 100, the source terminal S1, the drain terminal D1, the drain terminal D3, the source terminal S3, and the ground. A current I₂ (second current) supplied from the external power supply via the power supply terminal 100 flows in sequence of the power supply terminal 100, the source terminal S2, the drain terminal D2, the drain terminal D4, the source terminal S4, and the ground.

The p-type transistor 21p2 is a fourth p-type transistor having a gate terminal G7 (seventh control terminal) and cascode-connected to the p-type transistor 21p1 between the source terminal Si and the drain terminal D1.

The p-type transistor 22p2 is a fifth p-type transistor having a gate terminal G8 (eighth control terminal) and cascode-connected to the p-type transistor 22p1 between the source terminal S2 and the drain terminal D2.

The gate terminal G7 and the gate terminal G8 are connected to each other, and a first bias voltage is applied to the gate G7 and the gate terminal G8.

The n-type transistor 11n1 is a fourth n-type transistor having a gate terminal G9 (ninth control terminal) and cascode-connected to the n-type transistor 11n2 between the drain terminal D3 and the source terminal S3.

The n-type transistor 12n1 is a fifth n-type transistor having a gate terminal G10 (tenth control terminal) and cascode-connected to the n-type transistor 12n2 between the drain terminal D4 and the source terminal S4.

The gate terminal G9 and the gate terminal G10 are connected, and a second bias voltage is applied to the gate G9 and the gate terminal G10.

With the circuit configuration described above, a current mirror circuit constituted by the p-type transistors 21p1 and 22p1 and a current mirror circuit constituted by the n-type transistors 11n2 and 12n2 are connected between the power supply terminal 100 and the ground. Therefore, the current source circuit 6 has a feedback configuration in combination of the two current mirror circuits such that the current I₂ becomes a current copying the current I₁ and both the currents I₁ and I₂ have the same current value. Thus, those currents are less affected by the variations of the power supply voltage V_{DD}.

Furthermore, the p-type transistor 21p2 can make the current I₁ even less susceptible to the changes in the drain voltage of the p-type transistor 21p1. The p-type transistor 22p2 can make the current I₂ even less susceptible to the changes in the drain voltage of the p-type transistor 22p1. As a result, the tolerance to the variations of the power supply voltage V_{DD} can be further enhanced.

Moreover, the n-type transistor 11n1 can make the current I₁ even less susceptible to the changes in the drain voltage of the n-type transistor 11n2. The n-type transistor 12n1 can make the current I₂ even less susceptible to the changes in the drain voltage of the n-type transistor 12n2. As a result, the tolerance to the variations of the power supply voltage V_{DD} can be further enhanced.

FIG. 10 is a graph depicting the variation characteristics of the reference current I_{ref} with respect to the power supply voltage V_{DD} in the current source circuit 6 according to the fourth embodiment. FIG. 10 represents a relation between the power supply voltage V_{DD} and the reference current I_{ref} in the current source circuit 6. As seen from FIG. 10, in the current source circuit 6, the variations of the reference current I_{ref} are suppressed to be not more than 1% (0.75%: 8.04 mA to 8.1 mA) with respect to the variations of the power supply voltage V_{DD} (11%: 1.7 V to 1.9 V) by adopting the circuit configuration in which the p-type transistors 21p2 and 22p2 and the n-type transistors 11n1 and 12n1 are added to the current source circuit 1 according to the first embodiment.

Thus, the tolerance to the variations of the power supply voltage V_{DD} can be made more reliable.

While the current source circuit 6 according to this embodiment adopts the circuit configuration in which the p-type transistors 21p2 and 22p2 and the n-type transistors 11n1 and 12n1 are added to the current source circuit 1 according to the first embodiment, the current source circuit 6 according to this embodiment is just required to have a circuit configuration in which at least one of the above-mentioned four transistors is added to the current source circuit 1 according to the first embodiment.

While the current source circuit 6 according to this embodiment adopts the circuit configuration in which one transistor is cascode-connected to each of the four transistors constituting the current source circuit 1 according to the first embodiment, two or more transistors may be cascode-connected to each of those four transistors.

At least one of the four transistors cascode-connected in the current source circuit 6 according to this embodiment may be applied to the current source circuits 2 to 5 according to the first to third embodiments.

### Fifth Embodiment

A fifth embodiment will be described below in connection with an amplifier device including the current source circuit according to the first embodiment.

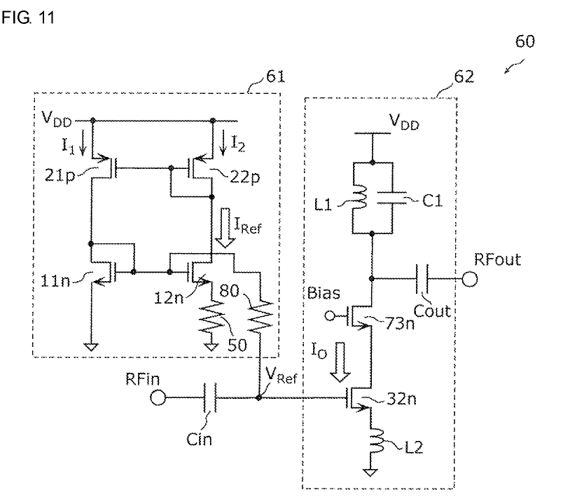

FIG. 11 is a circuit diagram of an amplifier device 60 according to the fifth embodiment. The amplifier device 60 illustrated in FIG. 11 includes a bias supply circuit 61 and an amplifier circuit 62. The amplifier device 60 amplifies a radio-frequency signal RFin, which is inputted from an input terminal, in the amplifier circuit 62, and outputs an amplified radio-frequency signal RFout from an output terminal. At that time, the performance of the amplifier circuit 62, such as an amplification factor, can be optimized with a reference voltage V_{ref} that is a bias voltage supplied from the bias supply circuit 61.

The bias supply circuit 61 generates the reference voltage V_{ref}, which is to be supplied to the amplifier circuit 62, on the basis of the reference current I_{ref} generated in the bias supply circuit 61, and supplies the reference voltage V_{ref} to the amplifier circuit 62. The bias supply circuit 61 is constituted by the circuit components in the circuit configuration of the current source circuit 1 according to the first embodiment except for the output n-type transistor 32n, and by a resistance element 80.

The resistance element 80 is connected between the gate terminal of the n-type transistor 12n and the gate terminal of the output n-type transistor 32n, and suppresses the reduction of an S/N (signal to noise) ratio, which may be caused by the leakage of the radio-frequency signal RFin to the bias supply circuit 61.

The amplifier circuit 62 is constituted by the output n-type transistor 32n in the current source circuit 1 according to the first embodiment, an n-type transistor 73n, inductors L1 and L2, and a capacitor C1. The output n-type transistor 32n and the n-type transistor 73n are cascode-connected, and a predetermined bias voltage is applied to a gate terminal of the n-type transistor 73n. A circuit constituted by the inductor L1 and the capacitor C1 connected in parallel with each other is connected to a drain terminal of the n-type transistor 73n. A DC cut capacitor Cin is connected to a path interconnecting the input terminal with the gate terminal of the output n-type transistor 32n, and a DC cut capacitor Cout is connected to a path interconnecting the drain terminal of the n-type transistor 73n with the output terminal. A connection node between the gate terminal of the output n-type transistor 32n and the capacitor Cin is connected to the gate terminal of the n-type transistor 12n in the bias supply circuit 61.

With the configuration described above, the radio-frequency signal RFin inputted from the input terminal is superimposed on the reference voltage V_{ref}, which is the bias voltage applied from the bias supply circuit 61, in a stage before entering the amplifier circuit 62, and then inputted to the amplifier circuit 62. The radio-frequency signal RFin inputted to the amplifier circuit 62 is amplified by the output n-type transistor 32n and the n-type transistor 73n, and is outputted from the output terminal.

Thus, since the bias supply circuit 61 generates the reference voltage V_{ref} that is not affected by the variations of the power supply voltage V_{DD} and the temperature changes, the amplifier device 60 having high tolerance to the variations of the power supply voltage V_{DD} and the temperature changes can be provided.

In the amplifier device 60 according to this embodiment, the current source circuit 1 according to the first embodiment is applied to the circuit configuration of the bias supply circuit 61 and a part of the amplifier circuit 62, but the present disclosure is not limited to that case. The amplifier device 60 according to this embodiment may be constituted by using, as the circuit configuration of the bias supply circuit 61 and a part of the amplifier circuit 62, any of the current source circuits 2 to 6 according to the first to fourth embodiments.

For instance, the amplifier device may be a combination of a bias supply circuit that includes the current source circuit 3 according to the second embodiment, which is constituted by the p-type transistors 23p and 24p, the n-type transistors 13n and 14n, and the resistance element 51, and an amplifier circuit that includes the output p-type transistor 34p having the gate terminal G6 to which the radio-frequency signal RFin and the reference voltage V_{ref} are applied. Such a combination can also provide the amplifier device having high tolerance to the variations of the power supply voltage V_{DD} and the temperature changes because the bias supply circuit generates the reference voltage V_{ref} that is not affected by the variations of the power supply voltage V_{DD} and the temperature changes.

### Other Embodiments, Etc.

While the current source circuits and the amplifier device according to embodiments of the present disclosure have been described above in connection with the first to fifth embodiments, the current source circuits and the amplifier device according to the present disclosure are not limited to the above-described embodiments. The present disclosure further includes other embodiments realized by optionally combining constituent elements in the above-described embodiments, modifications obtained by modifying the above-described embodiments based on various ideas conceivable by those skilled in the art within the scope not departing from the gist of the present disclosure, and various devices including the current source circuits and the amplifier device disclosed herein.

In the current source circuits and the amplifier device according to the above-described embodiments, other radio-frequency circuit elements, wirings and so on may be inserted between paths connecting the various circuit elements and signal paths, which are illustrated in the drawings.

The present disclosure can be widely utilized, in communication devices, as a current source circuit and an amplifier device each having high tolerance to the variations of an external power-supply voltage and the temperature changes.

While preferred embodiments of the disclosure have been described above, it is to be understood that variations and modifications will be apparent to those skilled in the art without departing from the scope and spirit of the disclosure. The scope of the disclosure, therefore, is to be determined solely by the following claims.

What is claimed is:

1. A current source circuit comprising:
a power supply terminal connected to an external power supply;
a first p-type transistor having a first terminal, a second terminal, and a first control terminal;
a second p-type transistor having a third terminal, a fourth terminal, and a second control terminal;
a first n-type transistor having a fifth terminal, a sixth terminal, and a third control terminal;
a second n-type transistor having a seventh terminal, an eighth terminal, and a fourth control terminal;
a third n-type transistor having a ninth terminal, a tenth terminal, and a fifth control terminal; and
a resistance element connected in series between the power supply terminal and the first terminal or between the eighth terminal and ground, wherein:
the second control terminal is connected to the first control terminal and the fourth terminal,
the third control terminal is connected to the fourth control terminal and the fifth terminal,
the fourth control terminal is connected to the fifth control terminal,
the tenth terminal is connected to ground,
a first current supplied from the external power supply flows from the power supply terminal to the first terminal, from the first terminal to the second terminal, from the second terminal to the fifth terminal, from the fifth terminal to the sixth terminal, and from the sixth terminal to ground,
a second current supplied from the external power supply flows from the power supply terminal to the third terminal, from the third terminal to the fourth terminal, from the fourth terminal to the seventh terminal, from the seventh terminal to the eighth terminal, and from the eighth terminal to ground, and
the resistance element has a positive temperature coefficient and thus has a resistance value that increases with temperature.

2. The current source circuit according to claim 1, comprising a plurality of third n-type transistors connected in parallel.

3. The current source circuit according to claim 1, wherein the first p-type transistor, the second p-type transistor, the first n-type transistor, the second n-type transistor, and the third n-type transistor are each Metal-Oxide-Semiconductor field-effect (MOSFET) transistors.

4. A current source circuit comprising:
a power supply terminal connected to an external power supply;
a first p-type transistor having a first terminal, a second terminal, and a first control terminal;
a second p-type transistor having a third terminal, a fourth terminal, and a second control terminal;
a first n-type transistor having a fifth terminal, a sixth terminal, and a third control terminal;
a second n-type transistor having a seventh terminal, an eighth terminal, and a fourth control terminal;
a third p-type transistor having an eleventh terminal, a twelfth terminal, and a sixth control terminal; and
a resistance element connected in series between the power supply terminal and the first terminal or between the eighth terminal and ground, wherein:
the second control terminal is connected to the first control terminal and the fourth terminal,
the third control terminal is connected to the fourth control terminal and the fifth terminal,
the second control terminal is connected to the sixth control terminal,
the eleventh terminal is connected to the power supply terminal,
a first current supplied from the external power supply flows from the power supply terminal to the first terminal, from the first terminal to the second terminal, from the second terminal to the fifth terminal, from the fifth terminal to the sixth terminal, and from the sixth terminal to ground,
a second current supplied from the external power supply flows from the power supply terminal to the third terminal, from the third terminal to the fourth terminal, from the fourth terminal to the seventh terminal, from the seventh terminal to the eighth terminal, and from the eighth terminal to ground, and
the resistance element has a positive temperature coefficient and thus has a resistance value that increases with temperature.

5. The current source circuit according to claim 4, comprising a plurality of third p-type transistors connected in parallel.

6. The current source circuit according to claim 4, wherein the first p-type transistor, the second p-type transistor, the first n-type transistor, the second n-type transistor, and the third p-type transistor are each Metal-Oxide-Semiconductor field-effect (MOSFET) transistors.

7. The current source circuit according to claim 1, wherein the first p-type transistor, the second p-type transistor, the first n-type transistor, and the second n-type transistor are each formed on or in a semiconductor substrate, and
the resistance element is formed by a p-type diffusion region or an n-type diffusion region of the semiconductor substrate.

8. The current source circuit according to claim 4, wherein the first p-type transistor, the second p-type transistor, the first n-type transistor, and the second n-type transistor are each formed on or in a semiconductor substrate, and
the resistance element is formed by a p-type diffusion region or an n-type diffusion region of the semiconductor substrate.

9. The current source circuit according to claim 1, further comprising:
a fourth p-type transistor having a seventh control terminal to which a first bias voltage is applied, the fourth p-type transistor being disposed between the first terminal and the second terminal and cascode-connected to the first p-type transistor, or
a fifth p-type transistor having an eighth control terminal to which the first bias voltage is applied, the fifth p-type transistor being disposed between the third terminal and the fourth terminal and cascode-connected to the second p-type transistor, or
both of the fourth p-type transistor and the fifth p-type transistor.

10. The current source circuit according to claim 4, further comprising:
a fourth p-type transistor having a seventh control terminal to which a first bias voltage is applied, the fourth p-type transistor being disposed between the first terminal and the second terminal and cascode-connected to the first p-type transistor, or
a fifth p-type transistor having an eighth control terminal to which the first bias voltage is applied, the fifth p-type transistor being disposed between the third terminal and the fourth terminal and cascode-connected to the second p-type transistor, or
both of the fourth p-type transistor and the fifth p-type transistor.

11. The current source circuit according to claim 1, further comprising:
a fourth n-type transistor having a ninth control terminal to which a second bias voltage is applied, the fourth n-type transistor being disposed between the fifth terminal and the sixth terminal and cascode-connected to the first n-type transistor, or
a fifth n-type transistor having a tenth control terminal to which the second bias voltage is applied, the fifth n-type transistor being disposed between the seventh terminal and the eighth terminal and cascode-connected to the second n-type transistor, or
both of the fourth n-type transistor and the fifth n-type transistor.

12. The current source circuit according to claim 4, further comprising:
a fourth n-type transistor having a ninth control terminal to which a second bias voltage is applied, the fourth n-type transistor being disposed between the fifth terminal and the sixth terminal and cascode-connected to the first n-type transistor, or
a fifth n-type transistor having a tenth control terminal to which the second bias voltage is applied, the fifth n-type transistor being disposed between the seventh terminal and the eighth terminal and cascode-connected to the second n-type transistor, or
both of the fourth n-type transistor and the fifth n-type transistor.

13. An amplifier device including the current source circuit according to claim 1, the amplifier device comprising:
a bias supply circuit comprising the first p-type transistor, the second p-type transistor, the first n-type transistor, the second n-type transistor, and the resistance element, the bias supply circuit being configured to generate a bias voltage, and
an amplifier circuit comprising the third n-type transistor configured to receive a radio-frequency input signal and the bias voltage at the fifth control terminal.

14. An amplifier device including the current source circuit according to claim 4, the amplifier device comprising:
a bias supply circuit comprising the first p-type transistor, the second p-type transistor, the first n-type transistor, the second n-type transistor, and the resistance element, the bias supply circuit being configured to generate a bias voltage, and
an amplifier circuit comprising the third p-type transistor configured to receive a radio-frequency input signal and the bias voltage at the sixth control terminal.
